(19) United States
(12) Patent Application Publication
(10) Pub. No.: US 2026/0202739 A1
(43) Pub. Date: Jul. 16, 2026

(54) METHOD FOR MANUFACTURING A PRINTING MOLD

(71) Applicant: COMMISSARIAT A L'ENERGIE ATOMIQUE ET AUX ENERGIES ALTERNATIVES, PARIS (FR)

(72) Inventors: Jérôme RECHE, GRENOBLE CEDEX 09 (FR); Maxime ARGOUD, GRENOBLE CEDEX 09 (FR)

(21) Appl. No.: 19/415,294

(22) Filed: Dec. 10, 2025

(30) Foreign Application Priority Data
Dec. 11, 2024 (FR) FR2413840

(51) Int. Cl. G03F 7/00

(52) U.S. Cl. CPC G03F 7/0002; G03F 7/0012; G03F 7/0017

(57) ABSTRACT

A method for manufacturing a printing mould includes providing a master mould with a structured surface having non-stickiness, the structured surface having a plurality of patterns; modifying only a portion of the structured surface so that said portion loses its non-stickiness, the portion including at least one of the patterns; forming a support on the structured surface, the support including a printing layer structured by the patterns; separating the support from the master mould to obtain the printing mould, a part of the printing layer remaining attached to the portion modified of the structured surface.

### TECHNICAL FIELD OF THE INVENTION

The present invention concerns the field of printing lithography. More particularly, the invention relates to a method for manufacturing a printing mould, commonly referred to as an intermediate mould or even working mould, from a master mould.

### TECHNOLOGICAL BACKGROUND OF THE INVENTION

Among the lithography techniques implemented in the microelectronics industry for the manufacture of integrated circuits, the nano-printing technique is attracting growing interest. This technique is based on printing a deformable material, typically a resin, with a mould. The mould includes patterns that are transferred to the resin during printing, with dimensions generally being between a few nanometres and several hundred micrometres.

There are two types of printing moulds: so-called “rigid” moulds and so-called “flexible” moulds.

One advantage of rigid moulds, for example those based on silicon substrates, is their mechanical strength, which makes them reusable many times over.

One advantage of flexible moulds, usually based on polymeric materials, is their ability to deform and thus make conformal contact over the entire surface to be printed, resulting in a more uniform distribution of the pressure applied by the mould. For this reason, flexible moulds are generally used to print layers with large surface areas, for example on substrates with a diameter greater than 100 mm. Further, their flexibility reduces the risk of breakage in the presence of dust between the surface to be printed and the mould. Removing a flexible mould pressed against a layer of lithography resin is easier, as it can be made by peeling.

Working moulds, whether flexible or rigid, can be made from a primary mould, commonly referred to as a master mould. One face of this master mould has patterns that form a negative image of the relief to be given to the working moulds. A same master mould can then be used to make several working moulds, which tends to reduce the cost of manufacturing these moulds.

The master mould is generally made by means of microelectronic manufacturing technologies (photolithography, etching, etc.) from a substrate of semiconductor material, for example silicon.

The working mould is generally obtained from the master mould by depositing a polymeric material in its liquid or semi-liquid state, referred to as resin, onto the master mould. This polymeric material is intended to form part of the working mould, namely the part with the patterns. To form a flexible mould, a flexible film of polymeric material can then be laminated onto the stack formed by the master mould and the resin layer. Alternatively, to form a harder mould, a rigid handle can be applied over the polymeric material. The whole is then exposed to electromagnetic radiation (usually ultraviolet radiation) and/or heat treatment to which the resin is sensitive. The resin is thus cured. It has a preferential stickiness to the flexible film or rigid handle rather than to the master mould, allowing it to be released from the master mould. The flexible film or rigid handle and the resin layer cured together form the working mould. The working mould has, in the resin layer cured, patterns with reverse polarity to those on the master mould (a projecting pattern becomes a recessed pattern, and vice versa).

The structured surface (that is the surface with the patterns) of the master mould can be coated with a non-stick layer in order to facilitate release of the working mould.

A drawback of this manufacturing method is that the working moulds made from a same master mould are all identical, which means that multiple master moulds are required.

### SUMMARY OF THE INVENTION

There is therefore a need for a printing mould manufacturing method that can be adapted to produce different moulds from a same master mould.

According to one aspect of the invention, this need tends to be met by providing a method for manufacturing a printing mould, comprising the following steps of:
providing a master mould with a structured surface having non-stickiness, the structured surface having a plurality of patterns;
modifying only a portion of the structured surface so that said portion loses its non-stickiness, said portion comprising at least one of the patterns;
forming a support on the structured surface, the support comprising a printing layer structured by the patterns;
separating the support from the master mould to obtain the printing mould, part of the printing layer remaining attached to the portion modified of the structured surface.

In one preferred mode of implementation of the manufacturing method, the master mould comprises a substrate and a non-stick layer disposed on the substrate, and the structured surface having non-stickiness belongs to the non-stick layer.

According to a first development of this preferred mode of implementation, the portion of the structured surface is modified by degrading a portion of the non-stick layer.

The portion of the non-stick layer is preferably degraded by a tip or by exposure to an electron beam, a laser, or a chemical solution.

According to a second development, the portion of the structured surface modified by completely removing a portion of the non-stick layer.

Forming the support on the structured surface may comprise the following sub-steps of:
depositing a curable resin layer onto the structured surface;
bringing a support layer into contact with the curable resin layer; and
curing the resin;
   the printing layer of the support being formed by the resin layer cured.

Alternatively, forming the support on the structured surface may comprise the following sub-steps of:
depositing a curable resin layer onto a support layer;
pressing the curable resin layer against the structured surface; and
curing the resin;
   the printing layer of the support being formed by the resin layer cured.

The support layer may be a flexible film or a rigid substrate.

The method may comprise, after the support separation step, a step of restoring the structured surface having non-stickiness.

### BRIEF DESCRIPTION OF THE FIGURES

Further characteristics and advantages of the invention will become clearer from the description thereof given below, by way of indicating and in no way limiting purposes, with reference to the appended figures, among which:

FIGS. 1A to 1F schematically represent a preferred mode of implementation of a printing mould manufacturing method according to the invention; and

FIGS. 2A to 2C schematically represent a lithography method using the printing mould manufactured.

For clarity, identical or similar elements are identified by identical reference signs throughout the figures.

### DETAILED DESCRIPTION

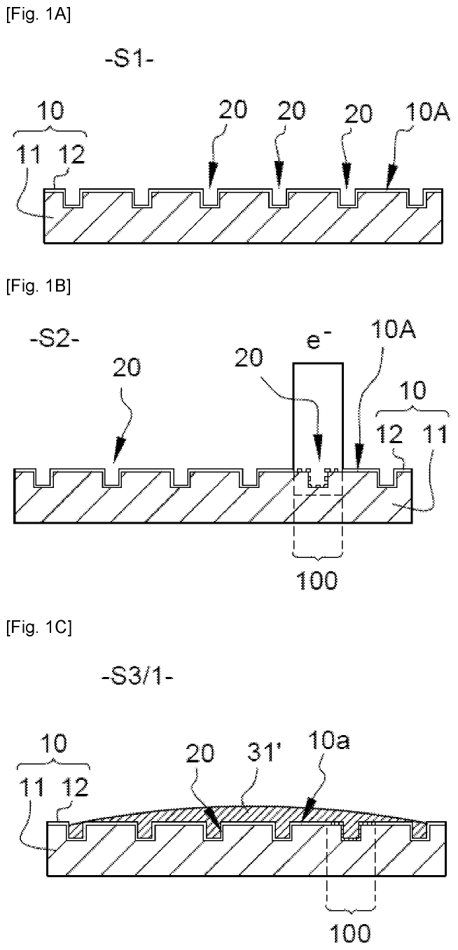

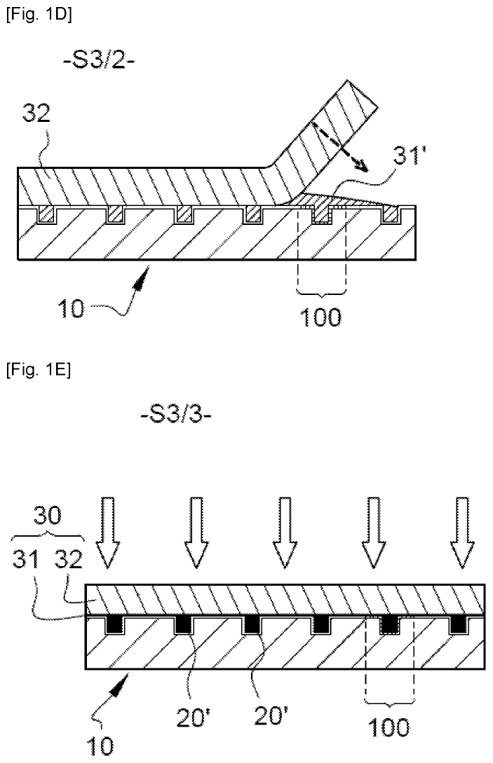

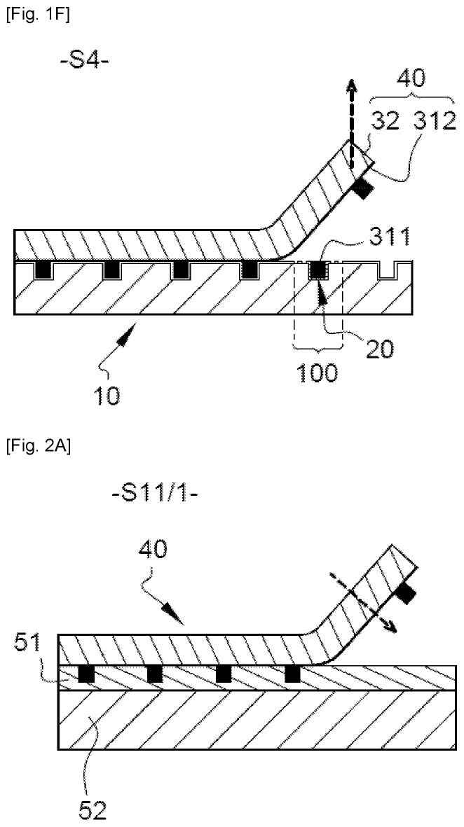

FIGS. 1A to 1F illustrate steps S1 to S4 of a method for manufacturing a printing mould according to one mode of implementation of the invention. The printing mould, also referred to as a working mould or intermediate mould, can be used in a printing lithography method within the scope of manufacturing microelectronic devices. Thus, the term “printing lithography mould” can also be employed to designate the printing mould.

In this preferred mode of implementation, the printing mould is flexible. In general, the flexibility of the printing mould (as well as the flexible support and flexible film described hereinafter) refers, alternatively or cumulatively, to:
its elastic deformability in order to snugly fit to a non-planar surface to be printed during printing, thereby making conformal contact over the entire surface to be printed;
its elastic deformability during at least one step of using the mould, such as lamination onto a surface to be printed or peeling;
the Young's modulus of its material or materials being less than 1 GPa;

its flexural deformability with a radius of curvature less than or equal to 1 m, preferably less than or equal to 5 cm.

With reference to FIG. 1A, the method first comprises a step S1 of providing a master mould 10, or master template, from which the printing mould will be manufactured. The master mould 10 has a structured surface 10A, that is a surface with patterns 20. The patterns 20 on the master mould 10 are topographical patterns, in other words, recessed or projecting patterns. Herein, the patterns 20 in question are recessed patterns. They may be holes, for example in the form of a straight cylinder, and/or lines.

The master mould 10 can be manufactured from a substrate 11, for example made of silicon, by means of manufacturing technologies used in the microelectronics industry, typically photolithography and etching.

The patterns 20 may have dimensions between 1 nm and 500 μm, preferably between 50 nm and 1 μm. In particular, the height of the patterns, measured perpendicularly to the main faces of the substrate 11, may be between 50 nm and 500 nm. Given that the printing mould will have patterns of the same dimensions as the patterns 20 of the master mould, but according to a polarity (negative image), the manufactured printing mould can be referred to as a nano-printing mould (insofar as it allows patterns of nanometric dimensions to be printed).

The structured surface 10A of the master mould 10 has non-stickiness, especially to facilitate subsequent releasing of the printing mould.

In this preferred mode of implementation, the master mould 10 comprises, further to the substrate 11, a non-stick layer 12 disposed on the substrate 11. The structured surface 10A, having non-stickiness, then belongs to the non-stick layer 12. In other words, the structured surface 10A is constituted by the non-stick layer 12.

In FIG. 1A, the patterns 20 are formed (preferably by etching) in the substrate 11 from one of its main faces, and the non-stick layer 12 covering the patterns 20 has a constant thickness. Thus, the aspect ratio of the patterns 20 is retained.

The non-stick layer 12 is, for example, a trichlorofluorosilane-type coating (conformally) deposited onto the substrate 11 by a Chemical Vapour Deposition (CVD) technique.

The master mould 10 may alternatively comprise a substrate 11 whose main faces are planar and a non-stick layer 12 with variable thickness, in which the patterns 20 are formed.

In one alternative implementation, not represented in the figures, the master mould 10 comprises only the substrate 11, one face of which is structured to form the patterns 20. Indeed, the substrate 11 may be formed of a material that already has (or intrinsically possesses) the desired stickiness, for example silicon with a contact angle with water of less than 10°. Alternatively, the substrate 11 may undergo a surface treatment enabling it to acquire this stickiness. By way of example, oxygen plasma or hexamethyldisilazane (HMDS) vapour deposition can be mentioned.

In step S2 of FIG. 1B, only a portion 100 of the structured surface 10A is modified so that this portion 100 loses its non-stickiness. Portion 100 contains at least one of the patterns 20 of the structured surface 10A. The remaining, unmodified portion of the structured surface 10A also comprises one or more patterns 20.

In the preferred mode of implementation of FIGS. 1A-1F, modifying the portion 100 of the structured surface 10A can be achieved either by degrading a portion of the non-stick layer 12 or by completely removing (i.e., over the entire thickness of the non-stick layer 12) a portion of the non-stick layer 12, for example by etching.

In the case of degradation, the non-stick layer 12 remains but becomes adhesive. Degradation may especially consist of an increase in the roughness of the non-stick layer 12 or a modification in the chemical affinity. The non-stick layer 12 may be degraded by a tip such as that of an atomic force microscope or by exposure to an electron beam, a laser or a chemical solution. By way of example, the non-stick layer 12 is (locally) degraded by exposure to an electron beam at a dose of 250 μc/cm².

In the case of etching, the substrate 11, which has stickiness, is partially exposed. The non-stick layer 12 can be (locally) etched by an oxygen-based plasma, for example.

The method then comprises a step S3 of forming a support 30 on the structured surface 10A of the master mould 10. This support 30 is herein flexible and is intended to form the flexible printing mould. It comprises a printing layer 31 structured by the patterns 20 of the master mould 10, and especially by the pattern or patterns 20 contained in the modified portion 100 of the structured surface 10A (see FIG. 1E). Thus, the printing layer 31 comprises (printing) patterns 20′corresponding to those of the master mould (of the same dimensions but in negative: here, a recessed pattern 20 becomes a projecting pattern 20′).

The printing layer 31 is formed from a deformable material so that it can be structured by the patterns 20. This deformable material is preferably a polymeric material in a liquid or semi-liquid (viscous) state, for example a curable resin.

FIGS. 1C to 1E illustrate a first mode of implementation of the step S3 of forming the support 30. In a first sub-step S3/1 represented by FIG. 1C, a curable resin layer 31′ is deposited onto the structured surface 10A. Preferably, the curable resin layer 31′ fills all the patterns 20 of the master mould 10 and forms a surplus thickness on the surface of the master mould 10. It is deposited, for example, by spin coating. And then, in a second sub-step S3/2 represented by FIG. 1D, a support layer, herein formed by a flexible film 32, is brought into contact with the curable resin layer 31′. The flexible film 32 can be laminated onto the curable resin layer 31′. Finally, the resin is cured during a third sub-step S3/3 represented in FIG. 1C.

In a second mode of implementation, step S3 of forming the support 30 comprises the following sub-steps of:
depositing a curable resin layer onto a support layer such as a flexible film;
pressing the curable resin layer against the structured surface; and
curing the resin;

In these two modes of implementation of step S3, the printing layer 31 of the support 30 is formed by the resin layer cured.

The resin may be photo-curable and/or heat-curable (also referred to as photosensitive or thermosensitive resin). In other words, it is cured (or cross-linked) by exposure to electromagnetic radiation (typically UV radiation) and/or heat treatment.

The curable resin may contain an inorganic filler in order to improve properties of the printing layer 31, typically its mechanical strength. The cured resin then forms a composite material comprising a polymer matrix and an inorganic filler. The inorganic filler is, for example, in the form of particles.

The flexible film 32 is preferably made of a polymeric material (alone) or a composite material. One example is polydimethylsiloxane (PDMS). Its thickness is advantageously between 1 μm and 10 μm. It gives the flexible mould its mechanical properties. Thus, its Young's modulus is advantageously less than 1 GPa and/or it is capable of undergoing flexural deformation with a radius of curvature less than or equal to 1 m, preferably less than or equal to 5 cm.

With reference to FIG. 1F, the manufacturing method includes a so-called mould release step S4, which consists of separating the support 30 from the master mould 10 to obtain the printing mould 40. This separation can be made by peeling, especially.

A part 311 of the printing layer 31 remains attached to the modified portion 100 of the structured surface 10A, made stick in step S2 of FIG. 1b. The printing mould 40 is formed by the support 30 herein comprising the remaining part 312 of the printing layer 31 and the flexible film 32. One or more patterns 20 of the master mould 10 located in the modified portion 100 are thus “plugged” by this part 311 of the printing layer 31 and are not found in the printing mould 40.

Thus, the stickiness or non-stickiness of the structured surface 10A, the non-stick layer 12 or the substrate 11 is understood relative to the material (possibly composite) of the printing layer 31.

The manufacturing method thus makes it possible to select which pattern(s) 20 of the master mould 10 will not be replicated in the printing mould 40. By virtue of this method, it is therefore possible to make printing moulds with different pattern distributions from a same master mould 10 (see FIG. 1A).

After manufacturing a first printing mould 40, the method may include a step of restoring the structured surface 10A having non-stickiness, thus returning to the stage of FIG. 1A. The part 311 of the printing layer 31 that has remained stuck to the master mould 10 can simultaneously be removed.

In the preferred mode of implementation described in relation to FIGS. 1A-1F, this restoration step may comprise a sub-step of removing the non-stick layer 12, preferably wet removal (example, peroxymonosulphuric acid solution), and a sub-step of forming a new non-stick layer on the substrate 11exposed.

And then, a second printing mould can be manufactured by again performing steps S2, S3 and S4 described above. The second printing mould is differentiated from the first printing mould by changing the modified portion 100 of the structured surface 10A at a location and/or its extent (in other words, by selecting at least one other pattern 20 or by reducing the number of patterns 20 in the portion 100).

The different printing moulds can serve in the manufacture of a same microelectronic device or to manufacture different microelectronic devices.

In one alternative implementation not represented in the figures, a rigid printing mould is obtained by replacing the flexible film 32 in the method of FIGS. 1A-1F (and more particularly in the steps of FIGS. 1D to 1F) with a rigid substrate, also referred to as a rigid handle (as a support layer). The rigid substrate is, for example, made of glass, quartz, silicon or a metal. It is brought into contact with the master mould 10, as well as mould released, either in parallel to the plane of the master mould 10 or at an angle (this facilitates detachment). As previously, the deformable material forming the printing layer 31 of the support 30 can be deposited either onto the master mould 10 (and then the rigid substrate comes thereabove) or on the support layer formed herein by the rigid substrate.

The manufacturing method has especially advantageous applications in the field of electronic identification or the security of electronic chips, areas where the aim is to form assemblies of different patterns.

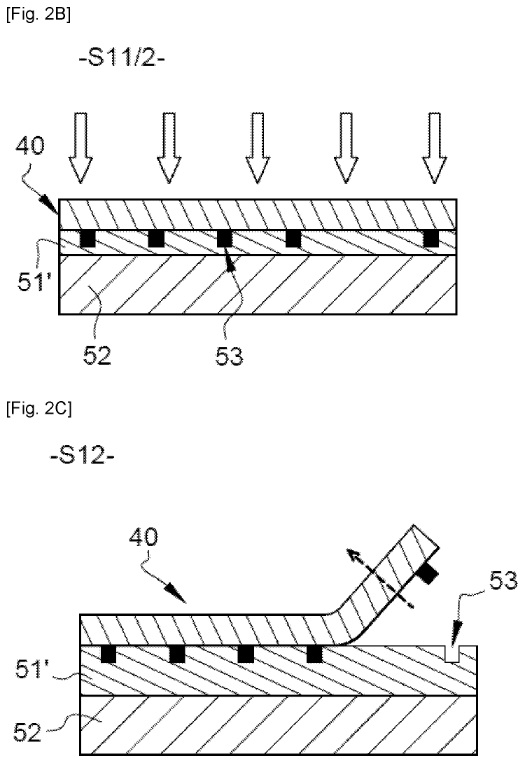

FIGS. 2A to 2C illustrate an example of the use of the printing mould 40: a lithography method by printing.

The lithography method includes a step S11 of printing, by means of the printing mould 40, patterns 53 in a layer of printable material 51 disposed on a target substrate 52.

When the layer of printable material 51 is formed of a curable (heat-curable and/or photo-curable) resin, the printing of the patterns 53 may comprise two sub-steps S11/1 and S11/2 represented by FIGS. 2A and 2B. In S11/1 (see FIG. 2A), the printing mould 40 is pressed against the resin layer 51 so as to transfer the patterns from the printing mould 40 to the resin layer 51. And then, in S11/2 (see FIG. 2B), the resin is cured (with the printing mould 40 still applied against the resin layer 51).

At the end of the printing step S1, a printed layer 51′, i.e. comprising patterns 53 corresponding to those of the printing mould 40, is obtained.

With reference to FIG. 2C, the lithography method then comprises a mould release step S12 of separating the printing mould 40 from the printed layer 51′. Mould release can be made by peeling in the case of a flexible printing mould.

Finally, after mould release, the lithography method may comprise a step of transferring the patterns 53 from the printed layer 51′ to the target substrate 52, for example by etching through the printed layer 51′ (the printed layer 51′ thus serving as an etching mask).

1. A method for manufacturing a printing mould, comprising:
providing a master mould with a structured surface having non-stickiness, the structured surface having a plurality of patterns;
modifying only a portion of the structured surface so that said portion loses its non-stickiness, said portion comprising at least one of the patterns;
forming a support on the structured surface, the support comprising a printing layer structured by the patterns;
separating the support from the master mould to obtain the printing mould, a part of the printing layer remaining attached to the portion modified of the structured surface.

2. The method according to claim 1, wherein the master mould comprises a substrate and a non-stick layer disposed on the substrate, and wherein the structured surface having non-stickiness belongs to the non-stick layer.

13. The method according to claim 2, wherein the portion of the structured surface is modified by degrading a portion of the non-stick layer.

4. The method according to claim 3, wherein the portion of the non-stick layer is degraded by a tip or by exposure to an electron beam, a laser or a chemical solution.

5. The method according to claim 2, wherein the portion of the structured surface has been modified by completely removing a portion of the non-stick layer.

6. The method according to claim 1, wherein forming the support on the structured surface comprises the following sub-steps of:
depositing a curable resin layer onto the structured surface;
contacting a support layer with the curable resin layer; and
curing the resin;
the printing layer of the support being formed by the resin layer cured.

717. The method according to claim 1, wherein forming the support on the structured surface comprises the following sub-steps of:
depositing a curable resin layer onto a support layer;
pressing the curable resin layer against the structured surface; and
curing the resin;
the printing layer of the support being formed by the resin layer cured.

8. The method according to claim 6, wherein the support layer is a flexible film or a rigid substrate.

19. The method according to claim 1, further comprising, after the step of separating the support, a step of restoring the structured surface having non-stickiness.
